(19) United States
(12) Patent Application Publication
(10) Pub. No.: US 2016/0088772 A1
(43) Pub. Date: Mar. 24, 2016

(54) METHOD AND APPARATUS TO REDUCE THERMAL RESISTANCE IN A SERVER CHASSIS

(71) Applicant: Avalanche Technology, Inc., Fremont, CA (US)

(72) Inventor: Ravishankar TADEPALLI, Fremont, CA (US)

(21) Appl. No.: 14/845,191

(22) Filed: Sep. 3, 2015

Related U.S. Application Data
(60) Provisional application No. 62/045,816, filed on Sep. 4, 2014.

(51) Int. Cl. H05K 7/20; H05K 7/14

(52) U.S. Cl. CPC H05K 7/20709; H05K 7/1488

(57) ABSTRACT

A server chassis includes add-on cards, interposer elements, and an interconnect subsystem including back planes. The interposer elements are physically connect to the at least two back planes and to the add-on cards therefore electrically coupling the add-on cards to the back planes. The add-on cards are configured in a stacked position such that unobstructed air flows between the add-on cards and through a space defined to be in between the back planes so that unobstructed air flow causes lowering of thermal resistance associated with the server chassis.

This application claims priority to U.S. Provisional Application No. 62/045,816, filed on Sep. 4, 2045, by Ravi and entitled “A Method And Apparatus To Reduce Thermal Resistance In A Server Chassis”.

### BACKGROUND OF THE INVENTION

1. Field of the Invention

The invention relates generally to a server chassis and more particularly to thermal resistance of add-on cards in the server chassis.

2. Description of the Prior Art

In a typical storage or networking server chassis, multiple add-on cards (also referred to as “boards” or “cards” with each board including storage elements) are coupled to each other and to possibly other boards and components, such as an (on-board) processor card, through an interconnect back plane. This interconnect back plane manages the signal routing including those for high speed signals, power signals, and auxiliary signals coupled between a processor bay and add-on card bay.

The physical location of the add-on card bay and processor bays in a server chassis is generally determined by the serviceability requirements of the chassis. As well known, these bays reside in front or in the back of the server chassis making it challenging to reach into the server chassis for servicing thereof.

An interconnect back plane is physically located in between the add-on card bay and the processor bay and typically creates an obstructions to the air flowing within the server chassis. Without adequate airflow, all sorts of problems are realized not to mention the obvious problem of overheating.

For various reasons, the interconnect back plane is either perforated or positioned at the bottom of the chassis, both of these schemes result in an increase of thermal resistance of the server chassis. The interconnect back plane also limits the ability to stack multiple add-on cards since it creates additional thermal resistance in the mid-plane of the chassis between two stacks of add-on-cards. High temperatures and increased thermal resistance adversely affect the functionality of the server chassis. To address this problem, currently, multiple high speed fans are employed. However, high speed fans also generate lots of noise and suffer from high power consumption and increased costs.

Add-on cards of a server chassis, such as one used in storage applications, are typically manufactured by a variety of manufacturers as opposed to a single manufacturer. These manufactures, in common applications, must meet certain international interface standards (or protocols), such as Peripheral Component Interconnect Express (PCIe), Serial AT Attachment (SATA), Self-Anchored Suspension Bridge (SAS) to name a few. These standards typically define certain requirements for connecting add-on cards with each other and/or other cards. Currently, these connectors are well suited as low-density chassis or for use in standalone applications.

Add-on cards generally include active as well as passive components, all of which consume significant amounts of power. Performance of these add-on cards is a function of temperature. Increased temperatures tend to degrade the performance of the add-on cards.

Accordingly, there is a need for a server chassis with reduced thermal resistance.

### SUMMARY OF THE INVENTION

Briefly, an embodiment of the invention includes a server chassis includes add-on cards, interposer elements, and an interconnect subsystem including back planes. The interposer elements are physically connect to the at least two back planes and to the add-on cards therefore electrically coupling the add-on cards to the back planes. The add-on cards are configured in a stacked position such that unobstructed air flows between the add-on cards and through a space defined to be in between the back planes so that unobstructed air flow causes lowering of thermal resistance associated with the server chassis.

### IN THE DRAWINGS

FIG. 1 show block diagram of a server chassis, involving various add-on cards, an interconnect subsystem, processor units, system power boards and system management boards, in accordance with an embodiment of the invention.

FIG. 2 shows a three dimensional perspective of a server chassis 200, in accordance with another embodiment of the invention.

FIG. 3 shows a server chassis 300, in accordance with an alternate embodiment of the invention.

### DESCRIPTION OF VARIOUS EMBODIMENTS

In the following description of the embodiments, reference is made to the accompanying drawings that form a part hereof, and in which is shown by way of illustration of the specific embodiments in which the invention may be practiced. It is to be understood that other embodiments may be utilized because structural changes may be made without departing from the scope of the present invention. It should be noted that the figures discussed herein are not drawn to scale and thicknesses of lines are not indicative of actual sizes.

To overcome the limitations in the prior art described above, and to overcome other limitations that will become apparent upon reading and understanding the subject specification, the invention includes methods and apparatus for reducing thermal resistance and in a server chassis (or “server chassis element”) including a stacked configuration of multiple add-on cards (or “storage cards”) connected to a processor bay.

In an embodiment and method of the invention, usage of one or more interposer cards is made in coupling the add-on cards to interconnect back planes of the server chassis. These interposer cards are translators between industry-standard connectors and commercially-available connectors.

In an embodiment of the invention, the server chassis experiences reduction of thermal resistance and audio noise that are generated by high-speed fans. The server chassis further experiences efficient cooling thereby increasing the reliability of the components therein, such as large numbers of add-on cards connected to a processor bay.

In the various embodiments of the invention discussed, referred to and/shown herein, a “server chassis element” refers to one or more subsystems within the server chassis. Some of the subsystems in a server chassis element include an add-on card bay and a processor bay, with the processor bay having a switch for coupling processors to associated add-on cards. A power board, another subsystem within the server chassis, serves as a source of power to the subsystems within the server chassis. Also included in the server chassis, as yet another subsystem, is a system management board that provides controls for various sensors and monitoring status for the remaining subsystems of the server chassis.

In accordance with an embodiment of the invention, the subsystems of the server chassis consume significant amounts of power during normal operations. To maintain a particular operating temperature within the proper limits of each of the components of the subsystems the heat that is generated by the subsystems is dissipated using efficient cooling systems. Avoiding inefficient cooling averts failure of components within the server chassis therefore frequent upgrades and increased costs for cooling down the server chassis are prevented.

In various embodiments to follow, a server chassis has multiple storage, networking, or compute (add-on) cards coupled to and aligned with interposer boards and mid-planes resulting in the reduction of thermal resistance.

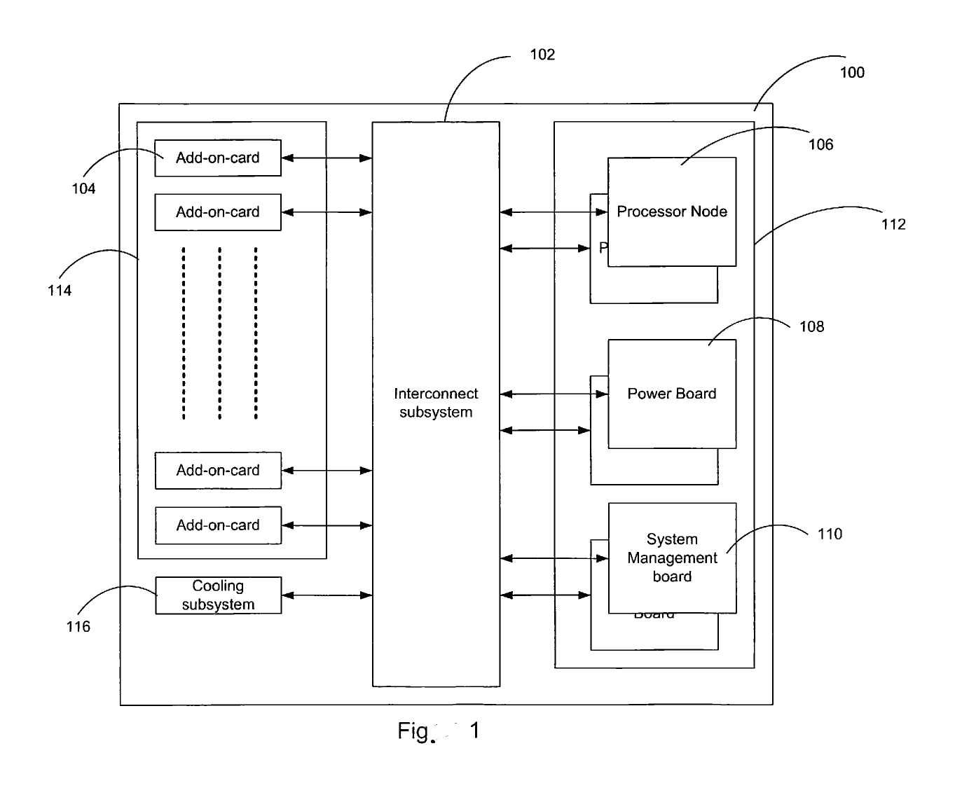

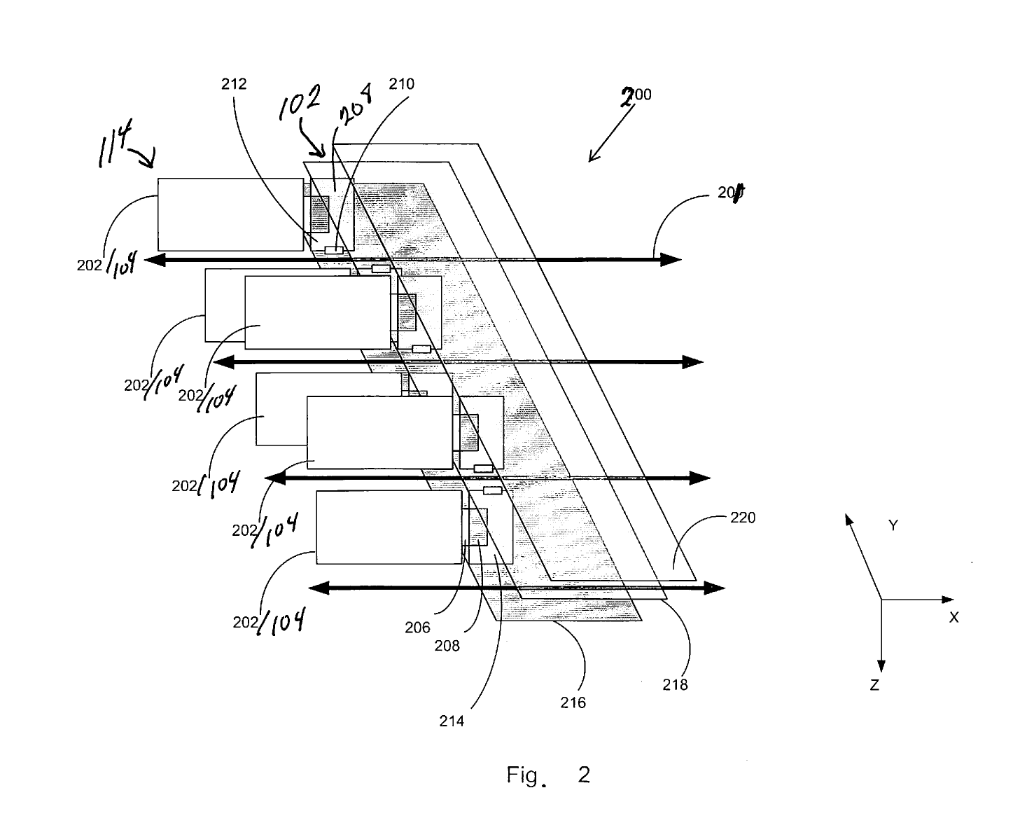

Referring now to FIG. 1, a server chassis 100 is shown, in accordance with an embodiment of the invention. The server chassis 100 is shown to include add-on card bay (or “subsystem”) 114, an interconnect subsystem 102, a cooling subsystem 116, and a processor bay (or “subsystem”) 112. The add-on card subsystem 114 is shown to include add-on cards 104 and the processor subsystem 112 is shown to include a number of processor node subsystem 106, a power board subsystem 108 and a system management board subsystem 110. The interconnect subsystem 102, while not shown in FIG. 2, includes interconnect back planes used for coupling the processor bay 112 to the add-on card bay 114. Also included in the interconnect subsystem 102 is one or more interposers, further discussed below relative to subsequent figures.

In a typical configuration, the subsystem 112 and the subsystem 102 form a permanent part of the server chassis 100 whereas the subsystem 114 changes in that its add-on cards 104 are connected to the subsystem 102 through an internal or external connected and can therefore be interchanged, increase in number or decrease in number.

Each of the add-on cards 104 is shown coupled to the interconnect subsystem 102, which is in turn shown coupled to the processor nodes of the processor subsystem 106, the power board subsystem 108, and the system management board subsystem 110.

The power board subsystem 108 provides power to all the components in the server chassis including the system management board subsystem 110.

Add-on cards 104 serve various functions, like storage, based on various technologies and network packet processors for various industry protocols and the like. In an embodiment of the invention, the add-on cards 104 conform to a standard protocol for interfaces such as without limitation, PCIe, SATA or SAS. Processor node subsystem 106 includes one or more central processing units (CPUs) along with system memory and switch circuitry for coupling the add-on cards 104 to each other based on the particular industry-standard requirements.

The interconnect subsystem (or “interconnect back plane” or “interconnect back plane element”) 102 couples the processor bay 112 with the add-on card bay 104, further explained below. Power board subsystem 108 provides the main power source of the server chassis 100, and it can also provide backup power to the components of server chassis 100 when needed.

In accordance with an embodiment of the invention, the system management board subsystem 110 monitors the temperature and voltage of various components of the server chassis 100, such as the subsystems shown in FIG. 1. One of its control functions is controlling the speed of a fan that may be placed inside of the server chassis 100. The interconnect subsystem 102 provides routing among the components of server chassis 100, among which are shown in FIG. 1 and described hereinabove.

The cooling subsystem 116 typically includes more than one fan located in front, in the rear or in the middle of the server chassis 100 or at multiple locations inside thereof. It is well known that in cooling subsystem designs, the physical location and number of fans depends on the thermal impedance and air pressure in various parts of the chassis.

In accordance with an embodiment of the invention, FIG. 2 shows a three dimensional perspective of a server chassis 200. The server chassis 200 is analogous to the server chassis 100 of FIG. 1 and in this respect includes the add-on cards 104 and the interconnect subsystem 102, with the add-on cards 104 shown nearly electrically coupled and mechanically connected to the interconnect subsystem 102. In FIG. 2, arrows 201 point in the general direction of airflow through the server chassis 200, which in an embodiment of the invention, is shown to be the horizontal direction such as a direction parallel to the width of this paper, i.e. the x-direction.

The interconnect subsystem 102 of the server chassis 100 is shown to include interconnect planes 216, 218 and 220 that each provide routing signals to the add-on cards 104, shown in FIG. 2 as add-on cards 202. The interconnect subsystem 102 is shown to be oriented along the y-axis or generally perpendicular to the direction of airflow.

It is well known to those skilled in the art of server chassis design that physical placement of fans can be done through the rear of the server chassis, in the middle of the server chassis, between the add-on card bay 114 and processor bay 112, or in front of the server chassis. Cool air enters from one end of the chassis and exits from the opposite end while dissipating heat from components, such as the add-on card bay and the processor bay. In the true spirit of the invention, similar schemes can be extended to systems with airflow from top to bottom or from bottom to top or to systems with airflow in between, front, or rear of the chassis and top or bottom of the chassis. Such schemes can be extended to other cooling subsystems including but not limited to blower fans.

The interconnect subsystem, in FIG. 2, other than the planes 216, 218 and 220 is shown to include interposer elements 214, outward interposer elements 212 for holding the add-on cards in place, connector plugs 206, receptacles 208, and connector elements 210. The connector elements 210 physically or mechanically connect the interposer elements 214 to one or more of the planes 216, 218 and 220. The plugs 206 are used to help the interposer elements 214 physically maintain the add-on cards in place. The receptacles 208 are holes or voids in the middle of the interposer elements, extending from the top of the add-on cards to the bottom of the add-on cards and can be effectively thought of as a part of the interposer elements. Generally, each interposer element 214 extends from a bottom surface of a one of the planes 216, 218 and 220 to a top surface of another one of the planes 216, 218 and 220. Alternatively, they may be shorter and partially extending the distance between two planes, in which case, the add-on cards may need to be smaller, at least in their vertical dimension. Still alternatively, the interposer elements 214 may be made to extend beyond two planes but this would require a more complex mechanical design of the server chassis.

While the interposer elements 214 are shown to have generally the shape of a “U” rotated about ninety degrees in the y-axis direction, other suitable shapes are contemplated.

In FIG. 2, each of the plugs 206 is shown to be positioned at a stem of the “U” of a corresponding interposer element while the connector elements 210 are positioned between the top and/or the bottom of the outward interposer elements 212 and a plane of the server chassis 200, i.e. planes 216, 218 and 220.

In continued reference to FIG. 2, outward interposer elements 212 each provide routing tracks between connector plugs 206 and receptacles 208 and connector element 210. Similar to outward interposer element 212, outward interposer element 214 provides routing tracks between a connector plug 206, a receptacle 208, and a connector element 210.

Interposer element 212 causes mechanical connection of the interconnect plane 216 to each of the add-on cards 202, thereby electrically coupling a respective one of the add-on cards 202 to the remaining subsystems and perhaps other components of the server chassis 200. Similarly, interposer element 214 causes mechanical connection of the add-on cards 202 to the interconnect plane 218 thereby electrically coupling a respective one of the add-on cards 202 to the remaining subsystems and/or components of the server chassis 200. Different interposer cards connecting to different interconnect planes provide the capability to disperse high-speed signal routing. This results in low routing density, less cross-talk and the capability to interconnect signals between stacks of add-on cards 104. “Stacks of add-on cards” refers to the configuration shown in FIG. 2 where some of the add-on cards 202 are shown positioned between interconnect plane 218 and interconnect plane 220 (or on top) and others of the add-on cards 202 are positioned between interconnect plane 218 and interconnect plane 216 (in the bottom). It is contemplated that while two sets of add-on cards 202 are shown stacked in FIG. 2, other number of stacks may be employed.

Interposer elements 212 and 214 can be extended to include proprietary connectors on both top edge and bottom edge of the interconnect planes 216, 218 and 220.

In the embodiment of FIG. 2, some of the add-on cards 202 are physically connected to interconnect planes 216 and 218 using interposer card elements 212 and 214; and some of the add-on cards 202 are physically connected to interconnect planes 218 and 220 using interposer cards 212 and 214. Add-on cards 202, interposer cards 212 and 214, and interconnect planes 216, 218 and 220 are aligned orthogonally along the y-axis and z-axis, respectively, relative to the direction of airflow shown by the arrows 200. This alignment allows for free air-flow through the server chassis 100 thereby reducing the total thermal resistance thereof.

Accordingly, in various embodiments of the invention, the interposer elements 212 and 214 are physically connected to the interconnect (back) planes and either directly or indirectly (through the plugs 206) are also physically connected to the add-on cards thereby causing an electrical coupling between the add-on cards and the interconnect back planes. The interconnect back planes with the help of the interposer elements 212 and 214 cause the add-on cards 202 to be configured in a stacked position such that unobstructed air flows between the add-on cards and through a space defined to be in between the interconnect back planes, in the direction of arrows 201. Unobstructed air flow causes the thermal resistance associated with the server chassis 200 to remain low or perhaps unchanged even in the face of added add-on cards.

In reference to FIG. 2, multiple back planes beyond the planes 216, 218 and 220 may be employed allowing for additional stacks of add-on cards while maintaining a low thermal resistance.

Several features of the various embodiments of the invention are evident to those skilled in the art after having read the following detailed description of the embodiments illustrated in the several figures of the drawing. The inventions described in the following figures can be extended to other non-obstructing schemes involving proprietary add-on cards, interconnect planes and processor bays or a standalone add-on card bay.

Referring still to FIG. 2, alternatively, horizontally-orientated add-on card 202 and interposer elements 212 and 214 can be connected to vertical interconnect planes, i.e. vertically-configured planes 216, 218, and 220. In the true spirit of the current invention, all such orthogonal orientations and scalable connectivity between add-on cards, interposer cards and interconnect back plane are considered as part of the low thermal resistance schemes.

The processor bay discussed relative to and shown in FIG. 1 is located generally in the planes 216, 218 and 220 or may be treated as the add-on cards 202, physically connecting to the planes 216-220 through interposer elements or otherwise.

In accordance with various embodiments of the invention, high-speed signals within the server chassis 200 are dispersed, at least in part due to the presence of multiple interposer cards positioned between multiple stacks of add-on cards and interconnect planes. Accordingly, the thermal resistance of the server chassis is not increased with the addition of more cards or is at least lower than that of prior art techniques.

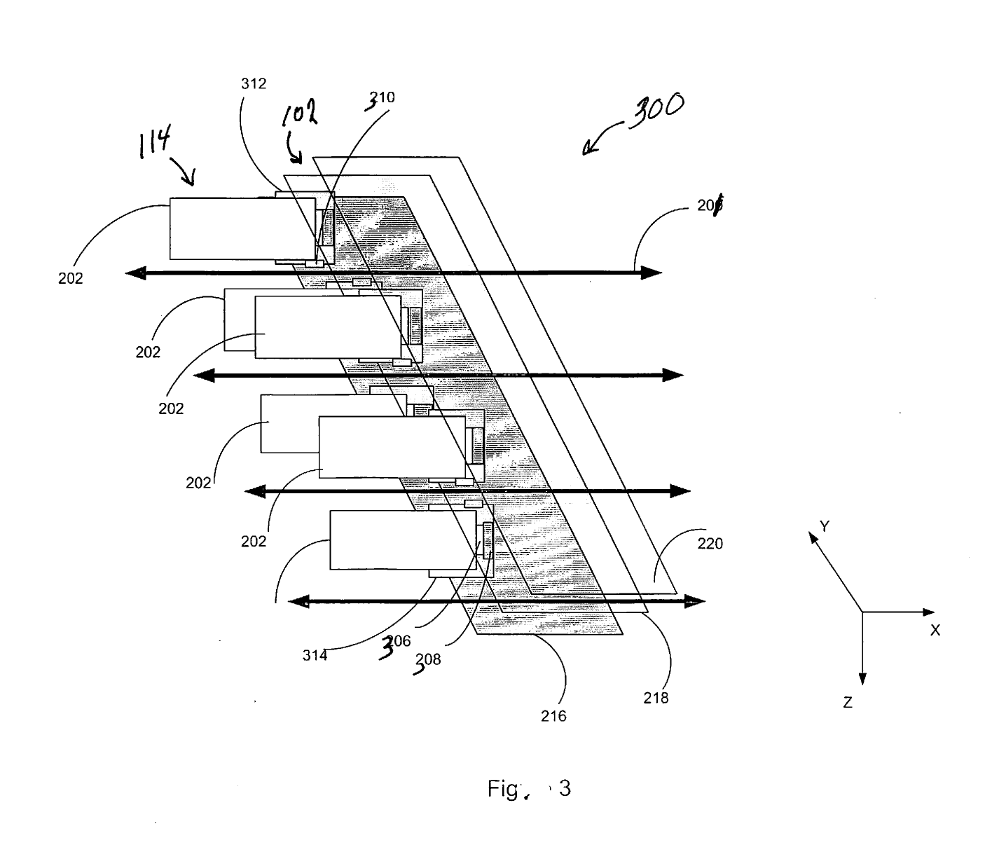

Referring now to FIG. 3, a server chassis 300 is shown as an alternate embodiment of the invention. The chassis 300 is analogous to the chassis 200 except that in place of outward interposer elements 212 and 214, inward interposer elements 312 and 314 are employed and therefore shown positioned between add-on-cards 202 and interconnect planes 216, 218 and 220. In the embodiment of FIG. 3, the connector elements 310, connector plugs 306 and the receptacles 308 serve generally the same purpose as their counterpart in FIG. 2. In the embodiment of FIG. 3 however, the top and bottom portions of the interposer elements 312 and 314 extend outwardly and onto the top and bottom of the add-on cards 202, respectively. In the true spirit of the current invention, all such orthogonal orientations involving variations in interposer cards are considered as part of the low thermal resistance schemes.

Thus, the server chassis 100, 200 or 300 may each have a very large number of add-on cards interfacing to the processor bay 112 and subject to high resistance to air-flow due to high density of interconnect planes. Generally, the larger the number of add-ons employed, the greater the number of interconnect planes needed. This results in inefficient air-flow and mandates usage of high powered fans to cool all the components in the system. With the embodiments and methods of the invention, reduction of thermal resistance of the interconnect planes allows high density of multiple stacks of add-on cards in the server chassis. With its low thermal resistance, all the bays including add-on card bay and processor bay are subject to efficient cooling resulting in lower noise and improved operation of the server chassis. This also reduces the power consumption of the cooling system bringing in significant benefits to various server applications and providing the ability to dissipate heat efficiently even in the face of high density and high power consuming applications.

Although the invention has been described in terms of specific embodiments, it is anticipated that alterations and modifications thereof will no doubt become apparent to those more skilled in the art. It is therefore intended that the following claims be interpreted as covering all such alterations and modification as fall within the true spirit and scope of the invention.

What is claimed is:

1. A server chassis comprising:
add-on cards;
interposer elements;
and an interconnect subsystem including at least two back planes, the interposer elements physically connected to the at least two back planes and to the add-on cards therefore electrically coupling the add-on cards to the at least two back planes, the add-on cards being configured in a stacked position such that unobstructed air flows between the add-on cards and through a space defined to be in between the at least two back planes,
wherein unobstructed air flow causes lowering of thermal resistance associated with the server chassis.

2. The server chassis of claim 1, wherein the add-on cards are in compliance with an industry-standard protocol.
